(19) United States
(12) Patent Application Publication
(10) Pub. No.: US 2011/0043384 A1
(43) Pub. Date: Feb. 24, 2011

(54) KEYBOARD

(75) Inventor: Yu-Chih Cheng, Taipei (TW)

Correspondence Address: KIRTON AND MCCONKIE, 60 EAST SOUTH TEMPLE,, SUITE 1800, SALT LAKE CITY, UT, 84111, US

(73) Assignee: PRIMAX ELECTRONICS LTD., Taipei (TW)

(21) Appl. No.: 12/614,023

(22) Filed: Nov. 6, 2009

(30) Foreign Application Priority Data
Aug. 21, 2009 (TW) 098128168

(51) Int. Cl. H03M 11/00

(52) U.S. Cl. 341/22

(57) ABSTRACT

A keyboard includes a plurality of keys and an illumination module. Each key includes a membrane switch structure, a scissors-type supporting member, a light-storing and light-adjusting elastic member, and a keycap. The light-storing and light-adjusting elastic member is accommodated within a receptacle of the scissors-type supporting member. The scissors-type supporting member contains a light-storing material. The light-storing material has a property of storing the radiant energy of the light from the light source and gradually emits visible ray in the dark. After the external light source is turned off, the radiant energy stored in the light-storing material could emit the visible ray for an afterglow time.

### FIELD OF THE INVENTION

The present invention relates to a keyboard, and more particularly to a keyboard having scissors-type membrane switch keys.

### BACKGROUND OF THE INVENTION

With increasing development of information industries, portable information devices such as notebook computers or personal digital assistants are widely used in many instances. In a case that a portable information device is used in a dim environment, the numbers and texts marked on the keys of the keyboard of the portable information device are usually invisible. In other words, the dim environment becomes hindrance from operating the keyboard. In addition, if the keyboard is used in the dim environment, the user is readily suffered from vision impairment. Recently, an illuminated keyboard has been disclosed. The illuminated keyboard could be used in the dim environment in order to enhance the applications thereof.

For example, Taiwanese Patent No. M292120 discloses an improved structure of an illuminated keyboard. The keyboard region is made of a transparent material or a translucent material. In a case that the keyboard region is made of a transparent material, the transparent material includes light-storing powder for allowing the keys of the keyboard region to absorb environmental light. Alternatively, an illumination module is disposed under the keyboard region for lighting the keys. The conventional keyboard, however, still has some drawbacks. For example, since the key of the keyboard region is made of a transparent material and the light-storing powder is contained in the key or distributed on the surface of the key, it is difficult to arrange the luminous region of the key. Therefore, there is a need of increasing the flexibility of arranging the luminous region of the key.

### SUMMARY OF THE INVENTION

It is an object of the present invention to provide a keyboard containing a light-storing material in specified components of the keys thereof while maintaining the original material of the keycap. When the light source is turned off, the key of the keyboard continuously emits light in order to achieve power-saving, tactile and aesthetically-pleasing benefits.

Another object of the present invention provides a keyboard with scissors-type membrane switch keys, in which a light-storing material is contained in the elastic members of the keys. By controlling the distributing condition of the light-storing material in the elastic member and the geometric shape of the elastic member, the light could be controlled to be guided to a desired luminous region of the keycap. As such, the flexibility of designing the luminous region of the keycap is enhanced.

A further object of the present invention provides a keyboard with scissors-type membrane switch keys, in which a light-storing material is contained in the elastic members of the keys and the elastic members are disposed under respective keycaps. As such, the light stored in the elastic members could be directly guided to the keycaps, and the intensity decline resulting from hindrance, absorption or scattering of other components will be avoided.

A still further object of the present invention provides a keyboard with scissors-type membrane switch keys, in which a light-storing material is contained in the elastic members of the keys and a scissors-type supporting member is retained. The use of the scissors-type support member causes stable movement of the keycap. The use of the light-storing material causes the keyboard to emit visible ray when the light source is turned off. As such, the cost of fabricating the light-storing keys is reduced.

In accordance with an aspect of the present invention, there is provided a keyboard. The keyboard includes a plurality of membrane switch structures, a plurality of keycaps, a plurality of light-storing and light-adjusting elastic members, a plurality of scissors-type supporting members and an illumination module. The keycaps are disposed on and aligned with respective membrane switch structures. The light-storing and light-adjusting elastic members are arranged between the keycaps and respective membrane switch structures for storing light and guiding the light to respective keycaps and triggering respective membrane switch structures to generate electronic signals. The scissors-type supporting members are arranged between the keycaps and respective membrane switch structures, and include respective receptacles for accommodating respective light-storing and light-adjusting elastic members. The illumination module is disposed under the scissors-type supporting members for providing the light to be stored in the light-storing and light-adjusting elastic members.

In an embodiment, the light-storing and light-adjusting elastic member is made of a composition containing a body material and a light-storing material, thereby guiding the light to a corresponding keycap.

In an embodiment, the light-storing and light-adjusting elastic member is made of a body material and a light-storing material is contained in a specified zone of the light-storing and light-adjusting elastic member, thereby guiding the light to a local region of a corresponding keycap.

In an embodiment, the light-storing and light-adjusting elastic member is made of a body material and a light-storing material is contained in a superficial region of the body material, thereby guiding the light to a corresponding keycap.

In an embodiment, the light-storing and light-adjusting elastic member is made of a body material and a light-storing material is partially contained in a superficial region of the body material, thereby guiding the light to a local region of a corresponding keycap.

The above objects and advantages of the present invention will become more readily apparent to those ordinarily skilled in the art after reviewing the following detailed description and accompanying drawings, in which:

### BRIEF DESCRIPTION OF THE DRAWINGS

FIGS. 1A, 1B and 1C are schematic cross-sectional views respectively illustrating membrane switch keys of three exemplary side-light keyboards according to a first embodiment of the present invention;

FIGS. 2A and 2B are schematic cross-sectional views respectively illustrating membrane switch keys of two exemplary direct-light keyboards according to a second embodiment of the present invention;

FIGS. 3A and 3B are schematic cross-sectional views respectively illustrating scissors-type membrane switch keys of two exemplary side-light keyboards according to a third embodiment of the present invention; and

FIGS. 4A, 4B and 4C are schematic cross-sectional views respectively illustrating scissors-type membrane switch keys of three exemplary direct-light keyboards according to a fourth embodiment of the present invention.

### DETAILED DESCRIPTION OF THE PREFERRED EMBODIMENT

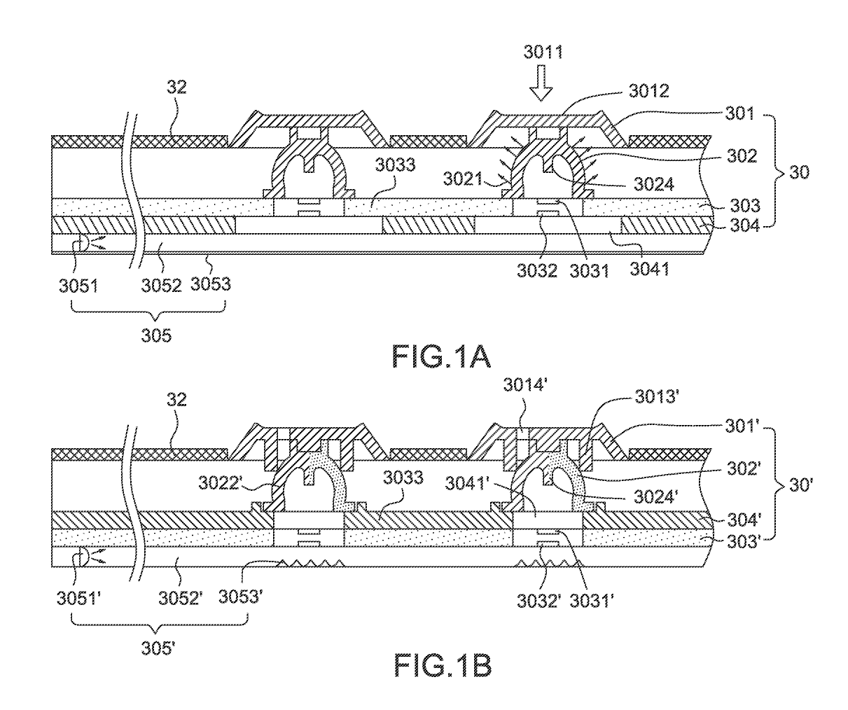

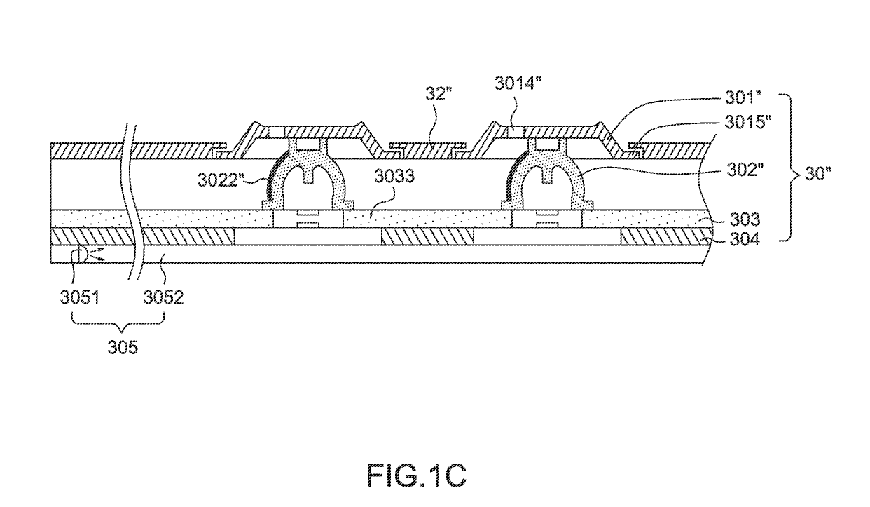

FIGS. 1A, 1B and 1C are schematic cross-sectional views respectively illustrating membrane switch keys of three exemplary side-light keyboards according to a first embodiment of the present invention. The configurations, shapes and arrangements of some components included in FIGS. 1A, 1B and 1C are distinguished but could be exchanged between each other. It is noted that, however, those skilled in the art will readily observe that numerous modifications and alterations may be made while retaining the teachings of the invention. The following descriptions of the side-light membrane switch keyboards of FIGS. 1A, 1B and 1C are presented herein for purpose of illustration and description only. As shown in FIG. 1A, a key 30 comprises an illumination module 305, a base plate 304, a membrane switch structure 303, a light-storing and light-adjusting elastic member 302, and a keycap structure 301. The keycap structure 301 (or a keycap) is disposed on the base plate 304 and shelters the light-storing and light-adjusting elastic member 302. The keycap structure 301 has a contact surface 3012 for receiving an external force 3011. The keycap structure 301 is made of a transparent material or an opaque material. A visible image or a text or a touchable protuberance could be directly printed on the contact surface 3012. Alternatively, after the whole contact surface 3012 is coated with ink, an image, a text or a touchable protuberance on the contact surface 3012 will be formed. The contact surface 3012 could be a flat surface or a curvy surface. FIG. 1B schematic illustrates another exemplary keycap structure 301′. The keycap structure 301′ is made of an opaque material. For allowing light to penetrate through the keycap structure 301′, the keycap structure 301′ further comprises a light-transmissible portion 3014′. For example, the light-transmissible portion 3014′ is a hollow portion that is filled with or covered with a transparent material.

As shown in FIG. 1A, a cover plate 32 including an opening is served as a fastening module for fixing the key 30. As shown in FIG. 1B, a portion of the keycap structure 301′ and the cover plate 32 are served as the fastening module. The portion of the keycap structure 301′ includes for example one or more key posts 3013′, which are extended from the bottom surface of the keycap structure 301′ and toward the base plate 304′ for fixing the keycap structure 301′ and the light-storing and light-adjusting elastic member 302′. As shown in FIG. 1C, the keycap structure 301″ of the key 30″ further includes one or more skirt plates 3015″, which are extended toward bilateral sides of the keycap structure 301″. The cover plate 32″ further includes skirt plates. The skirt plates of the cover plate 32″ and the keycap structure 301″ cooperate with each other to facilitate fixing the keycap structure 301″. It is to be understood that the keycap structure 301″ is not be limited to the disclosed embodiment.

Please refer to FIG. 1A again. The light-storing and light-adjusting elastic member 302 is arranged between the keycap structure 301 and the membrane switch structure 303 for storing light and guiding the light to the keycap structure 301 and triggering the membrane switch structure 303 to generate an electronic signal. In an embodiment, the light-storing and light-adjusting elastic member 302 is made of a composition containing a body material and a light-storing material. An example of the body material includes but is not limited to silicon rubber or other elastomeric material. An example of the light-storing material includes but is not limited to luminous PP fiber (or luminous polypropylene fiber). The light-storing material is uniformly distributed in the body material. The light-storing material has a property of storing the radiant energy of the light from the light source and gradually emits visible ray in the dark. After the external light source is turned off, the radiant energy stored in the light-storing material could emit the visible ray for a time period (i.e. an afterglow time). Due to the light-storing property of the light-storing material, the light-storing and light-adjusting elastic member 302 has the light-storing function. In this context, the term “light-storing function” indicates the function of allowing the electrons of the light-storing material to be in the excited state by absorbing radiant energy of external light. After the external light source is turned off, the electrons of the light-storing material are switched from the excited state to the ground state, so that the light-storing material could still emit light. In another embodiment, the light-storing and light-adjusting elastic member 302 is made of the body material, and the light-storing material is contained in a superficial region of the light-storing and light-adjusting elastic member 302. In addition, the light-storing and light-adjusting elastic member 302 has a dome-shaped geometry, so that the stored light could be guided to keycap structure 301 in the direction indicated by the arrow 3021. Under this circumstance, the luminous region is disposed within the covering range of the keycap structure 301. For example, the luminous region includes the whole region of the contact area 3012 or a specified local region of the contact area 3012.

Another light guiding means are shown in FIGS. 1B and 1C. As shown in FIG. 1B, the light-storing material is contained in a specified zone 3022′ of the light-storing and light-adjusting elastic member 302′ for more precisely guiding the light to the light-transmissible portion 3014′. As shown in FIG. 1C, the light-storing material is contained in a superficial region 3022″ of the light-storing and light-adjusting elastic member 302″ for more precisely guiding the light to the light-transmissible portion 3014″. From the above discussion, by controlling the distributing condition of the light-storing material in the light-storing and light-adjusting elastic member and the geometric shape of the light-storing and light-adjusting elastic member, the light could be controlled to be guided to the covering range or a desired luminous region of the keycap structure. Under this circumstance, the area of the illumination zone or the luminous region of the keycap structure could be precisely controlled.

Please refer to FIG. 1A again. The membrane switch structure 303 is disposed on the base plate 304. In a case that the membrane switch structure 303 is triggered by the light-storing and light-adjusting elastic member 302, the conductive contact points 3031 and 3032 of the membrane switch structure 303 will be contacted with each other, thereby generating an electronic signal. For example, when an external force is exerted on the keycap structure 301 to downwardly move the keycap structure 301, the external force is transmitted to the light-storing and light-adjusting elastic member 302. In response to the external force, the light-storing and light-adjusting elastic member 302 is subject to deformation and a salient 3024 of the light-storing and light-adjusting elastic member 302 gradually approaches the conductive contact point 3031. Meanwhile, the membrane switch structure 303 is also deformed, and thus the conductive contact points 3031 and 3032 will approach to each other. Until the conductive contact points 3031 and 3032 are in contact with each other, an electronic signal is generated. On the other hand, when the external force exerted on the keycap structure 301 is eliminated, the light-storing and light-adjusting elastic member 302 is restored to its original shape. As a consequence, the salient 3024 is not contacted with or separated from the membrane switch structure 303. In addition to the conductive contact points 3031 and 3032, the membrane switch structure 303 further comprises an insulating dielectric layer 3033. The insulating dielectric layer 3033 is arranged between the conductive contact points 3031 and 3032 for preventing from electrical connection between the conductive contact points 3031 and 3032 before the membrane switch structure 303 is triggered. Since the membrane switch structure 303 is relatively thin, the base plate 304 is attached on the membrane switch structure 303 for facilitating supporting the components over the membrane switch structure 303. In addition, the base plate 304 has a perforation 3041 corresponding to the light-storing and light-adjusting elastic member 302. In another embodiment, as shown in FIG. 1B, the base plate 304′ is disposed on the membrane switch structure 303′. The base plate 304′ has a perforation 3041′ corresponding to the light-storing and light-adjusting elastic member 302′. When the light-storing and light-adjusting elastic member 302′ is moved downwardly, the salient 3024′ of the light-storing and light-adjusting elastic member 302′ gradually approaches the conductive contact points 3031′ and 3032′ of the membrane switch structure 303′ through the perforation 3041′, and thus the conductive contact points 3031′ and 3032′ are in contact with each other. Moreover, the light emitted from the illumination module 305′ could be transmitted to the light-storing and light-adjusting elastic member 302 through the perforation 3041′.

Please refer to FIG. 1A again. The key 30 further comprises an illumination module 305. The illumination module 305 is disposed under the base plate 304. By the illumination module 305, the direction of the light emitted from a side-edge light source of the key 30 is changed such that the light is guided to the light-storing and light-adjusting elastic member 302. In this embodiment, the illumination module 305 comprises a light source 3051 and a backlight member 3052. The light source 3051 is arranged at a side edge of the backlight member 3052. The backlight member 3052 is made of transparent material. A surface of the backlight member 3052 is completely or selectively printed with or coated with a reflective layer 3053 for reflecting the light emitted from the light source 3051 to the light-storing and light-adjusting elastic member 302. Moreover, in the arrangement of FIG. 1A, the base plate 304 could be integrated into the illumination module 305, so that the illumination module 305 is also responsible for supporting the components of the keyboard. In another embodiment, as shown in FIG. 1B, the backlight member 3052′ of the illumination module 305′ is made of a reflective material. Optionally, the illumination module 305′ includes reflectors 3053′ for reflecting the light emitted from the light source 3051′ to the light-storing and light-adjusting elastic member 302′.

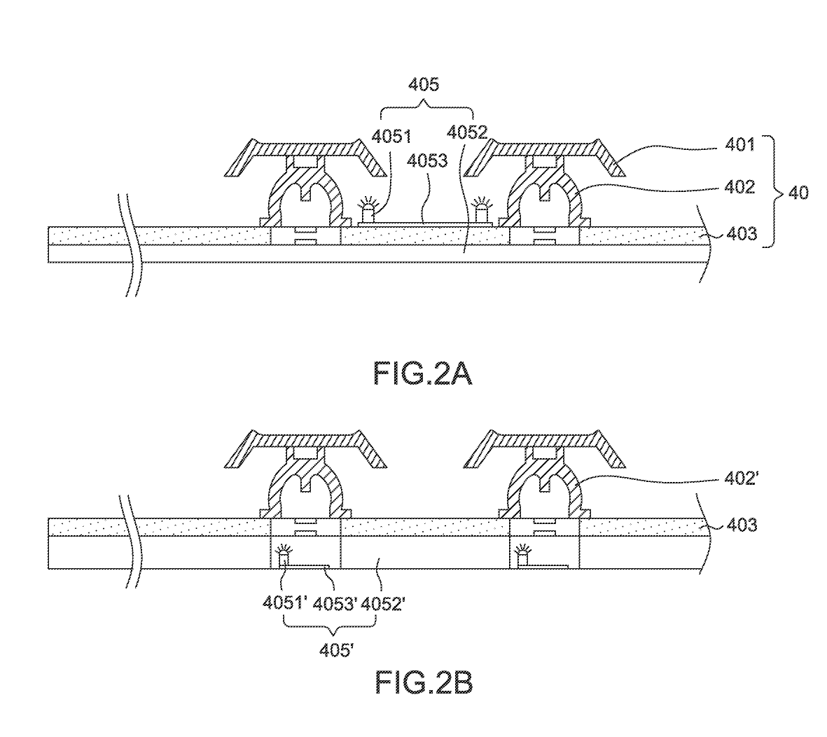

FIGS. 2A and 2B are schematic cross-sectional views respectively illustrating membrane switch keys of two exemplary direct-light keyboards according to a second embodiment of the present invention. The configurations, shapes and arrangements of some components included in FIGS. 2A and 2B are distinguished but could be exchanged between each other. It is noted that, however, those skilled in the art will readily observe that numerous modifications and alterations may be made while retaining the teachings of the invention. The following descriptions of the direct-light membrane switch keyboards of FIGS. 2A and 2B are presented herein for purpose of illustration and description only. As shown in FIG. 2A, a key 40 comprises an illumination module 405, a membrane switch structure 403, a light-storing and light-adjusting elastic member 402, and a keycap structure 401. The configurations and functions of the membrane switch structure 403, the light-storing and light-adjusting elastic member 402 and the keycap structure 401 are similar to those illustrated in FIGS. 1A, 1B and 1C, and are not redundantly described herein.

As shown in FIG. 2A, the illumination module 405 comprises a light source 4051 and a circuit board 4053, which are disposed over the membrane switch structure 403. The light source 4051 is arranged in the vicinity of the light-storing and light-adjusting elastic member 402. As such, the light emitted from the light source 4051 could be directly transmitted to the light-storing and light-adjusting elastic member 402, and the intensity decline resulting from passage through a component will be avoided. The illumination module 405 further comprises a backlight member 4052 (or a base plate), which is disposed under the membrane switch structure 403 for supporting other components of the key 40. In another embodiment, as shown in FIG. 2B, the light source 4051′ and the circuit board 4053′ of the illumination module 405′ are disposed within the backlight member 4052′ and arranged under the light-storing and light-adjusting elastic member 402′. In such manner, the light emitted from the light source 4051′ could be also transmitted to the light-storing and light-adjusting elastic member 402′ and stored in the light-storing and light-adjusting elastic member 402′.

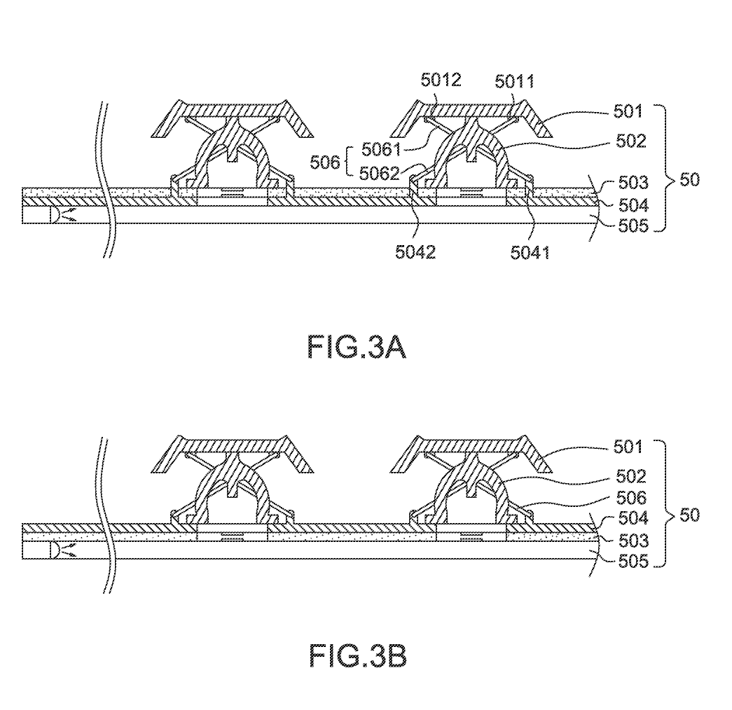

The light-storing and light-adjusting elastic member of the present invention could be applied to other types of keys. FIGS. 3A and 3B are schematic cross-sectional views respectively illustrating scissors-type membrane switch keys of two exemplary side-light keyboards according to a third embodiment of the present invention. As shown in FIG. 3A, a key 50 comprises a base plate 504, a membrane switch structure 503, a light-storing and light-adjusting elastic member 502, a keycap structure 501, an illumination module 505 and a scissors-type supporting member 506. The configurations and functions of the base plate 504, the membrane switch structure 503, the light-storing and light-adjusting elastic member 502 and the illumination module 505 are similar to those illustrated in the above embodiments, and are not redundantly described herein. The fastening module comprises first receiving parts 5011, 5012 of the keycap structure 501, the scissors-type supporting member 506, and second receiving parts 5041, 5042 of the base plate 504. The scissors-type supporting member 506 has a receptacle for accommodating the light-storing and light-adjusting elastic member 502. In addition, the scissors-type supporting member 506 is connected with the keycap structure 501 and the base plate 504 through the first receiving parts 5011, 5012 and the second receiving parts 5041, 5042, respectively. The scissors-type supporting member 506 comprises arm elements 5061 and 5062. The arm elements 5061 and 5062 are rotatable. In a case that an external force is exerted on the keycap structure 501, the arm elements 5061 and 5062 are rotated to be in a folded status. Whereas, in a case that the external force is eliminated, the arm elements 5061 and 5062 are rotated to be in a stretched status. In some embodiments, the scissors-type supporting member 506 contains the light-storing material, so that the scissors-type supporting member 506 has light-storing efficacy. Except that the base plate 504 is disposed on the membrane switch structure 503, the side-light keyboard of FIG. 3B is substantially identical to that of FIG. 3A. Moreover, the other components are similar to those illustrated in FIGS. 2A and 2B, and are redundantly described herein.

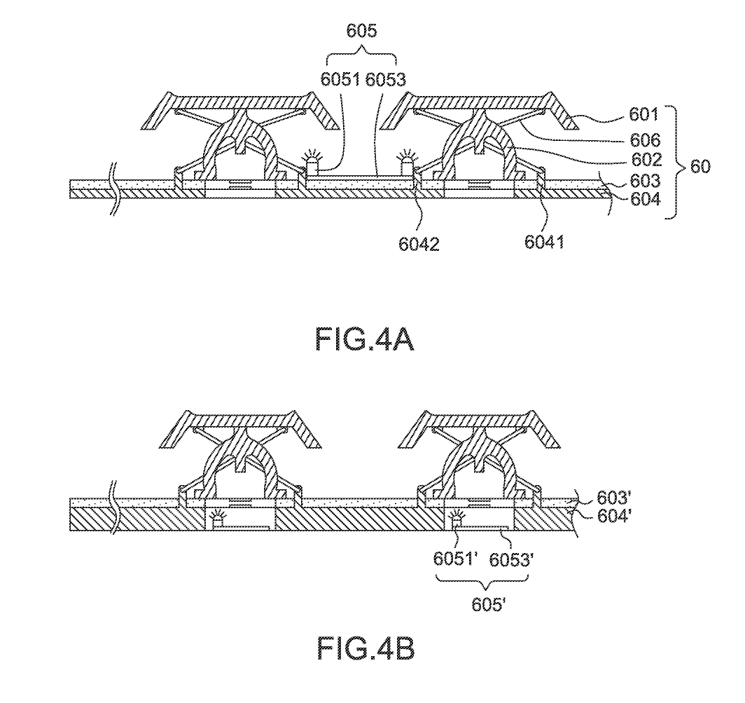

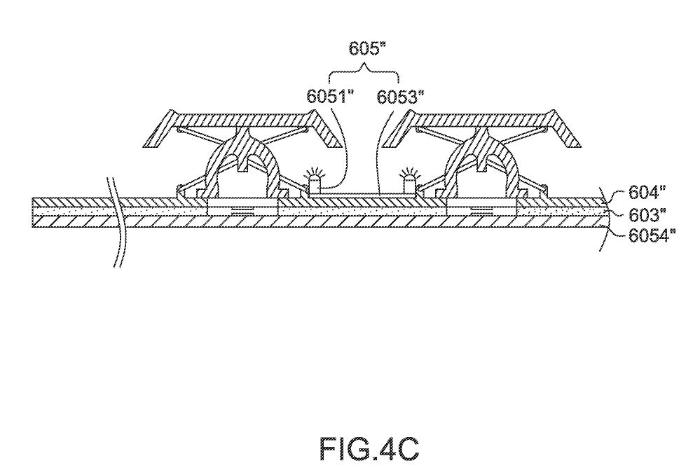

The light-storing and light-adjusting elastic member of the present invention could be applied to other types of keys. FIGS. 4A, 4B and 4C are schematic cross-sectional views respectively illustrating scissors-type membrane switch keys of three exemplary direct-light keyboards according to a fourth embodiment of the present invention. The base plate, the membrane switch structure, the light-storing and light-adjusting elastic member and the keycap structure included in FIGS. 4A, 4B and 4C are similar to those illustrated in FIGS. 1A, 1B and 1C. The illumination module included in FIGS. 4A, 4B and 4C is similar to those illustrated in FIGS. 2A and 2B. The scissors-type supporting member included in FIGS. 4A, 4B and 4C are similar to those illustrated in FIGS. 3A and 3B. As shown in FIG. 4A, a key 60 comprises a base plate 604, a membrane switch structure 603, a light-storing and light-adjusting elastic member 602, a keycap structure 601 and a scissors-type supporting member 606. The membrane switch structure 603 is disposed on the base plate 604. The receiving parts 6041 and 6042 of the base plate 604 penetrate through corresponding holes of the membrane switch structure 603 and connected with the scissors-type supporting member 606. The illumination module 605 comprises a light source 6051 and a circuit board 6053, which are disposed over the membrane switch structure 603. The light source 6051 is arranged in the vicinity of the light-storing and light-adjusting elastic member 602. As such, the light emitted from the light source 6051 could be directly transmitted to the light-storing and light-adjusting elastic member 602. As shown in FIG. 4B, the base plate 604′ is disposed on the membrane switch structure 603′. The illumination module 605′ comprises a light source 6051′ and a circuit board 6053′, which are disposed under the membrane switch structure 603′. Like the arrangement of FIG. 2B, the light emitted from the light source 6051′ could be also transmitted to the light-storing and light-adjusting elastic member 602′ and stored in the light-storing and light-adjusting elastic member 602′. As shown in FIG. 4C, the base plate 604″ is disposed on the membrane switch structure 603″. The illumination module 605″ comprises a light source 6051″, a circuit board 6053″ and another base plate 6054″. The base plate 6054″ is disposed on the membrane switch structure 603″ for supporting the keyboard.

In the above embodiments, after the components of the key are assembled and in response to a depressing force transmitted from the keycap, the light-storing and light-adjusting elastic member is deformed to be contacted with the membrane switch structure and the membrane switch structure is triggered to generate an electronic signal. The light emitted from the light source has a wavelength of 200˜450 mm. The light emitted from the light source is reflected by the backlight member and guided to the light-storing and light-adjusting elastic member. Alternatively, the light emitted from the light source is directly projected on the light-storing and light-adjusting elastic member. By absorbing radiant energy of the light, the light-storing and light-adjusting elastic member starts to emit visible ray and store the radiant energy of the light. After the light source has emitted light for a certain time period, the light source is turned off under control of the computer or by operating a control key of the keyboard. Meanwhile, the light-storing capacity of the light-storing and light-adjusting elastic member reaches a specified level or a saturation level. After the light source is turned off, the radiant energy stored in the light-storing material of the light-storing and light-adjusting elastic member could emit the visible ray for an afterglow time of about 10 hours.

From the above description, since the use of the light-storing and light-adjusting elastic member could emit the visible ray after the light source is turned off, the illuminated keyboard of the present invention is power-saving. Moreover, by controlling the geometric shape of the light-storing and light-adjusting elastic member, the stored light could be guided to the keycap structure, so that the keycap structure looks completely illuminated for the user. Since the light-storing and light-adjusting elastic member is directly disposed under the keycap structure, the visible ray generated from the light-storing and light-adjusting elastic member is not hindered by other components. In addition, the light reflected by the backlight member is directly transmitted to the light-storing and light-adjusting elastic member without being hindered by other components. Due to the backlight member, a good back lighting effect is achieved. Since the elastic member is an essential component of the general key, no additional component is required. In other words, the keyboard of the present invention is very cost-effective.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A keyboard comprising:
a plurality of membrane switch structures;
a plurality of keycaps disposed on and aligned with respective membrane switch structures;
a plurality of light-storing and light-adjusting elastic members arranged between said keycaps and respective membrane switch structures for storing light and guiding said light to respective keycaps and triggering respective membrane switch structures to generate electronic signals;
a plurality of scissors-type supporting members arranged between said keycaps and respective membrane switch structures, and comprising respective receptacles for accommodating respective light-storing and light-adjusting elastic members; and
an illumination module disposed under said scissors-type supporting members for providing said light to be stored in said light-storing and light-adjusting elastic members.

2. The keyboard according to claim 1 wherein said light-storing and light-adjusting elastic member is made of a composition containing a body material and a light-storing material, thereby guiding said light to a corresponding keycap.

3. The keyboard according to claim 1 wherein said light-storing and light-adjusting elastic member is made of a body material and a light-storing material is contained in a specified zone of said light-storing and light-adjusting elastic member, thereby guiding said light to a local region of a corresponding keycap.

4. The keyboard according to claim 1 wherein said light-storing and light-adjusting elastic member is made of a body material and a light-storing material is contained in a superficial region of said body material, thereby guiding said light to a corresponding keycap.

5. The keyboard according to claim 1 wherein said light-storing and light-adjusting elastic member is made of a body material and a light-storing material is partially contained in a superficial region of said body material, thereby guiding said light to a local region of a corresponding keycap.

6. The keyboard according to claim 1 wherein said illumination module comprises:
a backlight member disposed under said membrane switch structures; and
a light source disposed at a side edge of said backlight member, wherein said light is emitted from said light source and reflected to said light-storing and light-adjusting elastic member by said backlight member.

7. The keyboard according to claim 6 wherein said illumination module further comprises a base plate, wherein said base plate is arranged between said membrane switch structures and said illumination module, and said scissors-type supporting members are connected with respective keycaps and said base plate.

8. The keyboard according to claim 6 wherein said illumination module further comprises a base plate, wherein said base plate is arranged between said membrane switch structures and said scissors-type supporting members, and said scissors-type supporting members are connected with respective keycaps and said base plate.

9. The keyboard according to claim 1 wherein said illumination module comprises:
a base plate disposed under said membrane switch structures, wherein said scissors-type supporting members are connected with respective keycaps and said base plate; and
a plurality of light sources disposed on respective membrane switch structures and arranged in the vicinity of respective light-storing and light-adjusting elastic members.

10. The keyboard according to claim 1 wherein said illumination module comprises:
a backlight member disposed under said membrane switch structures; and
a plurality of light sources disposed within said backlight member and arranged in the vicinity of respective light-storing and light-adjusting elastic members.

11. The keyboard according to claim 1 wherein said illumination module comprises:
a first base plate disposed over said membrane switch structures, wherein said scissors-type supporting members are connected with respective keycaps and said first base plate;
a plurality of light sources disposed on said first base plate and arranged in the vicinity of respective light-storing and light-adjusting elastic members; and
a second base plate disposed under said membrane switch structures for supporting said keyboard.
